(19) United States
(12) Patent Application Publication
(10) Pub. No.: US 2008/0266806 A1
(43) Pub. Date: Oct. 30, 2008

(54) ELECTRONIC ASSEMBLY THAT INCLUDES A HEAT SINK WHICH COOLS MULTIPLE ELECTRONIC COMPONENTS

(76) Inventors: Eric D. Lakin, Chippewa Falls, WI (US); Paul Bonstrom, Eau Claire, WI (US)

Correspondence Address: SCHWEGMAN, LUNDBERG & WOESSNER, P.A., P.O. BOX 2938, MINNEAPOLIS, MN, 55402, US

(21) Appl. No.: 11/741,550

(22) Filed: Apr. 27, 2007

(51) Int. Cl. H05K 7/20

(52) U.S. Cl. 361/709

(57) ABSTRACT

The electronic assembly includes a substrate that has a first side and a second side. The electronic assembly further includes first and second electronic components that are mounted on the first side of the substrate. The first electronic component extends a different height above the first side of the substrate as the second electronic component. The electronic assembly further includes a heat sink that includes a base and fins which extend from the base. The base of the heat sink includes a formation which engages the second electronic component in order to maintain the base of the heat sink in substantially parallel relation to the substrate. In some embodiments, the formation in the base of the heat sink is a detent, while in other embodiments the formation in the base of the heat sink is a projection.

### FEDERALLY SPONSORED RESEARCH OR DEVELOPMENT

The U.S. Government has a paid-up license in this invention and the right in limited circumstances to require the patent owner to license others on reasonable terms as provided for by the terms of Contact No. MDA904-02-3-0052, awarded by the Maryland Procurement Office.

### BACKGROUND OF THE INVENTION

1. Field of the Invention

The present invention is related to electronic assemblies, and more particularly to electronic assemblies that include a heat sink which cools multiple electronic components.

2. Background Information

Electronic devices generate heat during operation. Thermal management refers to the ability to keep temperature-sensitive elements in an electronic device within a prescribed operating temperature.

Historically, electronic devices have been cooled by natural convection. The cases or packaging of the devices included strategically located openings (e.g., slots) that allowed warm air to escape and cooler air to be drawn in.

The advent of high performance electronic devices now requires more innovative thermal management. Each increase in processing speed and power generally carries a “cost” of increased heat generation such that natural convection is no longer sufficient to provide proper thermal management. If the heat generated by such electronic devices is not removed at a sufficient rate, the devices may overheat resulting in damage to the devices and/or a reduction in operating performance of the devices.

One common method of cooling an electronic device includes thermally coupling a heat sink to an electronic device. A typical heat sink includes protrusions (e.g., fins or pins) which project from a body of the heat sink. The protrusions give the heat sink a larger surface area such that the heat sink dissipates a greater amount of thermal energy from the electronic device into the surrounding environment. Heat sinks are fabricated from materials with high thermal conductivity in order to efficiently transfer thermal energy from the electronic device to the ambient environment.

A fan is often used in conjunction with the heat sink to improve the heat sink's rate of cooling. The fan causes air to move past the fins on the heat sink. Moving air past the heat sink increases the rate of convection between the heat sink and the ambient environment where the heat sink is located. Increasing the rate of convection between the heat sink and the ambient environment reduces the temperature of the heat sink, thereby enhancing the heat sink's ability to transfer heat from the electronic device.

There are several drawbacks with cooling systems that include a heat sink and fan combination. One drawback is that the fan must typically be located quite close to the fins of the heat sink to generate fully developed air flow. The overall configuration of many electronic devices often makes it difficult to locate a fan near a heat sink that is attached to an electronic component which requires cooling within an electronic device.

In addition, when a fan is too far from an electronic component, a large percentage of the air moved by the fan does not go through the heat sink. As a result, even large fans are often not an efficient solution for cooling some electronic devices.

The ability to thermally manage electronic devices becomes even more difficult when multiple electronic components are mounted in close proximity to one another within an electronic system. As an example, multiple chipsets, dies, processors, memory modules and/or application specific integrated circuits (hereafter asics) may be mounted in close proximity to one another on a substrate (e.g., a printed circuit board or a daughter card) such that the heat generated by each electronic component can adversely effect the performance that particular component as well as the other electronic components.

The heat sinks in existing electronic assemblies often do not effectively cool high performance electronic components when multiple electronic components are mounted in close proximity to one another on a substrate within an electronic device. Therefore, what is needed is an electronic assembly which includes a heat sink that provides high performance cooling to multiple high powered electronic components when the electronic components are mounted in close proximity to one another on a substrate.

### BRIEF DESCRIPTION OF THE DRAWINGS

FIG. 1 illustrates a schematic side view of an example electronic assembly.

FIG. 2 illustrates a schematic side view of another example electronic assembly.

FIG. 3 illustrates a schematic side view of another example electronic assembly.

FIG. 4 is an exploded perspective view of another example electronic assembly.

FIG. 5 is a plan view of the opposing side of the substrate shown in FIG. 4.

FIG. 6 illustrates the electronic assembly shown in FIG. 4 where the electronic assembly further includes a printed circuit board and a connector that connects the printed circuit board to the substrate.

### DETAILED DESCRIPTION OF THE INVENTION

In the following detailed description of the preferred embodiments, reference is made to the accompanying drawings which form a part hereof, and in which is shown by way of illustration specific embodiments in which the invention may be practiced. It is to be understood that other embodiments may be utilized and structural changes may be made without departing from the scope of the present invention.

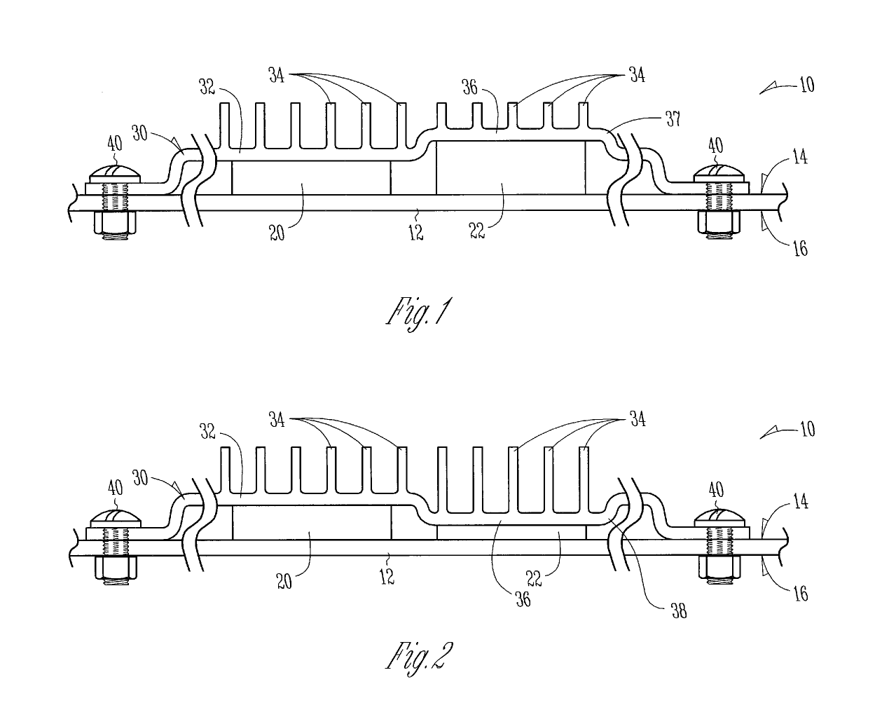

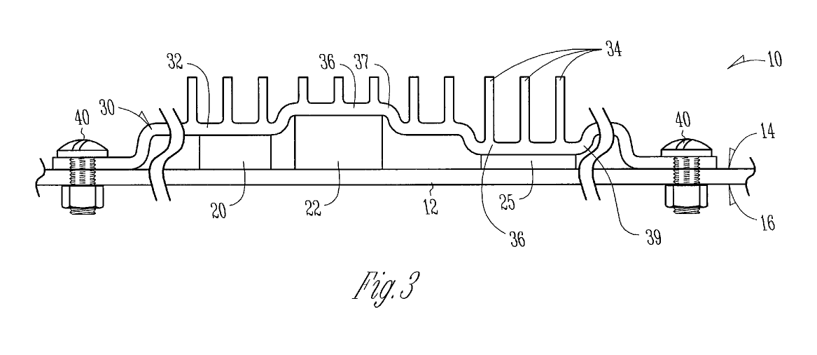

FIGS. 1 and 2 illustrate an example electronic assembly 10 according to the present invention. The electronic assembly 10 includes a substrate 12 that has a first side 14 and a second side 16. The electronic assembly 10 further includes a first electronic component 20 that is mounted on the first side 14 of the substrate 12 and a second electronic component 22 that is mounted on the first side 14 of the substrate 12. As shown in FIGS. 1 and 2, the first electronic component 20 extends a different height above the first side 14 of the substrate 12 as the second electronic component 22.

The electronic assembly 10 further includes a heat sink 30 that includes a base 32 and fins 34 which extend from the base 32. The base 32 of the heat sink 30 includes a formation 36 which engages the second electronic component 22 in order to maintain the base 32 of the heat sink 30 in substantially parallel relation to the substrate 12.

In the example embodiment illustrated in FIG. 1, the formation 36 in the base 32 of the heat sink 30 is a detent 37, while in the example embodiment illustrated in FIG. 2, the formation 36 in the base 32 of the heat sink 30 is a projection 38. It should be noted that in other embodiments, the formation 36 may engage the first electronic component 20 instead of the second electronic component 22. In addition, the determination as to whether the formation is a detent 37 or a projection 38 will depend in part on (i) the configuration of the first and second electronic components 20, 22; (ii) the configuration of the base 32 and fins 34 of the heat sink 30; (iii) the arrangement of the first and second electronic components 20, 22 on the substrate; and/or (iv) manufacturing considerations associated with electronic assembly 10.

Maintaining the base 32 of the heat sink 30 in substantially parallel relation to the substrate 12 makes it easier move air (e.g., by using a fan) past the fins 34 of the heat sink. Therefore, the heat sink is more readily able to provide high performance cooling to the first and second electronic components 20, 22.

The ability to provide high performance cooling may be especially important when the first and second electronic components 20, 22 are relatively high powered devices that are mounted in close proximity to one another on the substrate 12. In some embodiments, the first electronic component 20 is an application specific integrated circuit and the second electronic component 22 is a memory device.

As shown in FIGS. 1 and 2, the heat sink 30 may engage the substrate 12 such that the heat sink 30 is mounted directly to the substrate 12. In some embodiments, the electronic assembly 10 further includes fasteners 40 that extend through the heat sink 30 and the substrate 12 in order to secure the heat sink 30 to the substrate 12.

It should be noted that any number and type of fasteners 40 may be used to secure the heat sink 30 to the substrate 12. In other embodiments, the heat sink 30 may be secured to the substrate 12 in some manner besides using fasteners (e.g., by using an adhesive).

Although FIGS. 1 and 2 show that the heat sink 30 and the substrate 12 may fully enclose the first electronic component 20 and the second electronic component 22, it should be noted that in some embodiments the heat sink 30 and the substrate 12 may only partially enclose the first electronic component 20 and the second electronic component 22. The determination as to whether the heat sink 30 and the substrate 12 fully or partially enclose the first electronic component 20 and the second electronic component 22 will depend in part on the arrangement of the first and second electronic components 20, 22 on the substrate and/or the manufacturing considerations that are associated with electronic assembly 10.

Although the heat sink 30 is shown as a unitary structure in the FIGS., it should be noted that the heat sink 30 may be formed from more than one structure that is joined together to form heat sink 30. As an example, the fins 34 may be one or more sectional inserts that extend through opening(s) in the base 32 and are attached to the base 32.

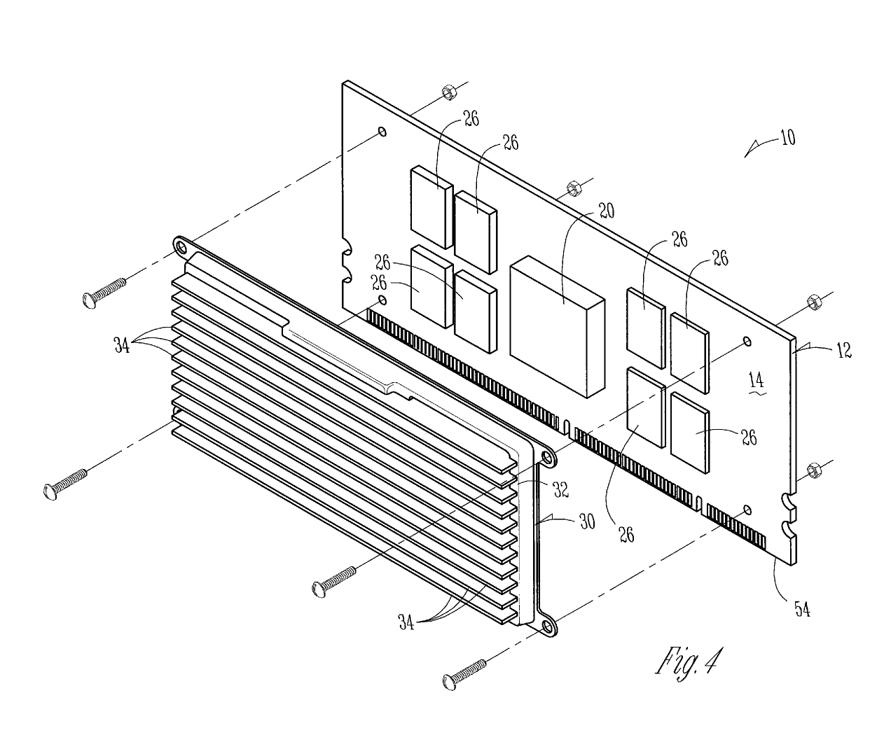

In the example embodiment illustrated in FIG. 3, the electronic assembly 10 further includes a third electronic component 25 that is mounted on the first side 14 of the substrate 12. The base 32 of the heat sink 30 includes another formation 36 (i.e., projection 39) which engages the third electronic component 25 in order to maintain the base 32 of the heat sink 30 substantially parallel to the substrate 12.

It should be noted that in other embodiments, the formation 36 may be a detent depending on the height of the third electronic component 25 relative to the other electronic components. In addition, although the third electronic component 25 is illustrated as extending a different height above the first side 14 of the substrate 12 as the first and second electronic components 20, 22, the third electronic component 25 may extend the same height above the first side 14 of the substrate 12 as the first electronic component 20 or the second electronic component 22.

In some embodiments, the third electronic component 25 is a memory device. It should be noted that any number of additional electronic components (e.g., memory devices) may also be placed on substrate 12 and engaged by the base 32 of heat sink 30.

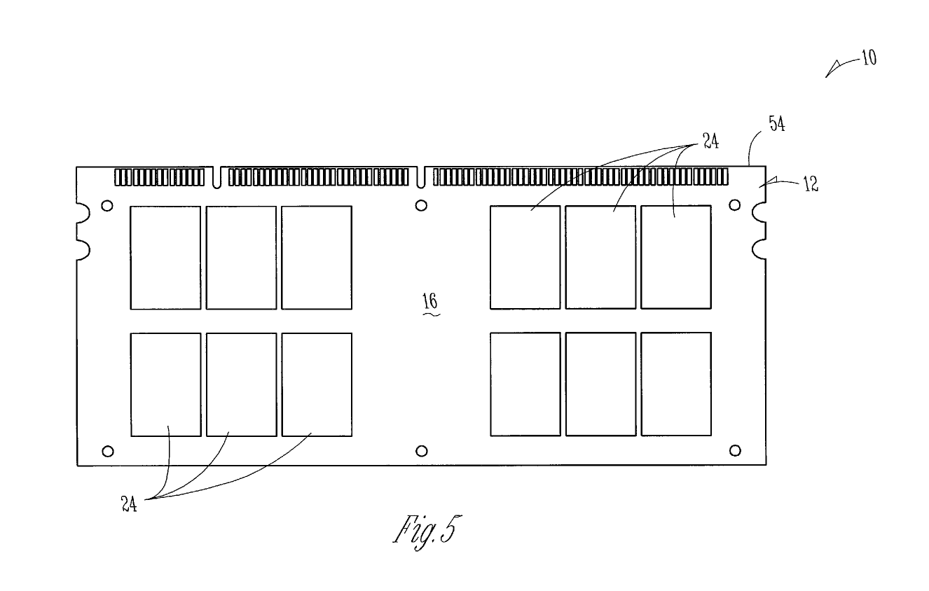

FIG. 4 is an exploded perspective view of another example electronic assembly 10. In this example embodiment, the electronic assembly 10 includes four memory devices 26 on one side of the application specific integrated circuit 22 and four more memory devices 26 on an opposing side of the application specific integrated circuit 22.

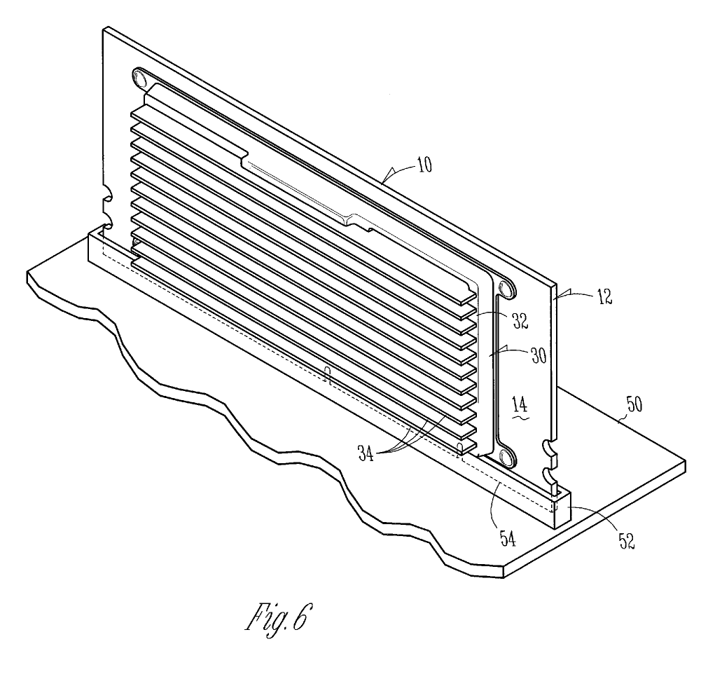

FIG. 5 is a plan view of the opposing side of the substrate 12 shown in FIG. 4. In some embodiments, the electronic assembly 10 may further include at least one additional electronic component mounted on the second side 16 of the substrate 12. As an example, FIG. 5 shows where additional memory devices 29 are mounted on the second side 16 of the substrate 12. The particular number and arrangement of electronic components on the substrate 12 will depend in part on the desired operation and function for the electronic assembly 10 within an electronic device.

FIG. 6 illustrates an example embodiment of the electronic assembly 10 where the electronic assembly 10 further includes a printed circuit board 50 and a connector 52 that connects the printed circuit board 50 to the substrate 12. In the illustrated example embodiment, the substrate 12 includes a lateral edge 54 such that the connector 52 engages the lateral edge of the substrate 12. It should be noted that although the substrate 12 is shown as being orthogonal to the printed circuit board 50, the substrate 12 may be at other angles relative to the printed circuit board 50.

Although specific embodiments have been illustrated and described herein, it will be appreciated by those of ordinary skill in the art that any arrangement which is calculated to achieve the same purpose may be substituted for the specific embodiment shown. This application is intended to cover any adaptations or variations of the present invention. Therefore, it is intended that this invention be limited only by the claims and the equivalents thereof.

1. An electronic assembly comprising:
a substrate that includes a first side and a second side;
a first electronic component mounted on the first side of the substrate;
a second electronic component mounted on the first side of the substrate, the first electronic component extending a different height above the first side of the substrate as the second electronic component; and
a heat sink that includes a base and fins extending from the base, the base of the heat sink including a formation which engages the second electronic component in order to maintain the base of the heat sink substantially parallel to the substrate when the heat sink is mounted in thermal contact with the first and second electronic components, wherein the heat sink and the substrate form an enclosure that encloses the first electronic component and the second electronic component.

2. The electronic assembly of claim 1, wherein the heat sink engages the substrate.

3. The electronic assembly of claim 2, wherein the heat sink is mounted directly to the substrate.

4. The electronic assembly of claim 3, further comprising fasteners that extend through the heat sink and the substrate in order to secure the heat sink to the substrate.

5. The electronic assembly of claim 1, wherein the formation in the base of the heat sink is a detent.

6. The electronic assembly of claim 1, wherein the formation in the base of the heat sink is a projection.

7. (canceled)

8. The electronic assembly of claim 1, further comprising a third electronic component mounted on the first side of the substrate, the base of the heat sink engaging the third electronic component.

9. The electronic assembly of claim 8, wherein the third electronic component extends a different height above the first side of the substrate as the first electronic component and the second electronic component.

10. The electronic assembly of claim 9, wherein the base of the heat sink includes another formation which engages the third electronic component in order to maintain the base of the heat sink substantially parallel to the substrate.

11. The electronic assembly of claim 8, wherein the third electronic component extends a same height above the first side of the substrate as the first electronic component.

12. The electronic assembly of claim 1, wherein the first electronic component is an application specific integrated circuit.

13. The electronic assembly of claim 12, wherein the second electronic component is a memory device.

14. The electronic assembly of claim 13, further comprising a plurality of additional memory devices that are mounted on the first side of the substrate, the base of the heat sink engaging each of the memory devices.

15. The electronic assembly of claim 13, further comprising seven additional memory devices, wherein four of the memory devices are on one side of the application specific integrated circuit and the remaining four more memory devices are on an opposing side of the application specific integrated circuit.

16. The electronic assembly of claim 15, further comprising:
a printed circuit board; and
a connector that connects the printed circuit board to the substrate.

17. The electronic assembly of claim 16, wherein the substrate includes a lateral edge such that the connector engages the lateral edge of the substrate.

18. The electronic assembly of claim 17, wherein the substrate is orthogonal to the printed circuit board.

19. The electronic assembly of claim 1, further comprising at least one additional electronic component mounted on the second side of the substrate.

20. The electronic assembly of claim 19, wherein the first electronic component is an application specific integrated circuit, the second electronic component is a memory device and the additional electronic components are memory devices.
